(19) United States
(12) Patent Application Publication
(10) Pub. No.: US 2007/0120153 A1
(43) Pub. Date: May 31, 2007

(54) Rugged MESFET for Power Applications

(75) Inventors: Richard K. Williams, Sunnyvale, CA (US); Jan Nilsson, (US)

Correspondence Address: ADVANCED ANALOGIC TECHNOLOGIES, 830 EAST ARQUES AVE, SUNNYVALE, CA, 94085, US

(73) Assignee: ADVANCED ANALOGIC TECHNOLOGIES, INC., Sunnyvale, CA (US)

(21) Appl. No.: 11/307,201

(22) Filed: Jan. 26, 2006

Related U.S. Application Data
(60) Provisional application No. 60/597,408, filed on Nov. 29, 2005.

(51) Int. Cl. H01L 31/112

(52) U.S. Cl. 257/280

(57) ABSTRACT

A rugged MESFET for power applications includes a drain region surrounded by a ring shaped gate. The gate is surrounded, in turn by a source region. This eliminates the high-field point between gate and drain along the device's etched mesa surface and results in improved avalanche capability.

### RELATED APPLICATIONS

This application is one of a group of concurrently filed applications that include related subject matter. The six titles in the group are: 1) High Frequency Power MESFET Gate Drive Circuits, 2) High-Frequency Power MESFET Boost Switching Power Supply, 3) Rugged MESFET for Power Applications, 4) Merged and Isolated Power MESFET Devices, 5) High-Frequency Power MESFET Buck Switching Power Supply, and 6) Power MESFET Rectifier. Each of these documents incorporates all of the others by reference.

### BACKGROUND OF INVENTION

DC-to-DC conversion and voltage regulation is an important function in virtually all electronic devices today. In low voltage applications, especially thirty volts and less, most switching regulators today use insulated-gate power transistors known as power MOSFETs. Power MOSFETs, despite certain high-frequency efficiency and performance limitations, have become ubiquitous in handheld electronics power by Lilon batteries (i.e. operating a 3V and higher voltages). In applications powered by single-cell NiMH and alkaline batteries where must operate with as little as 0.9V of battery voltage, however, these limitations are more severe. With such low voltage conditions, power MOSFETs exhibit inefficient and unreliable operation, lacking the gate drive necessary to switch between their low-leakage “off” state and a low-resistance “on” state. With manufacturing variations in their threshold voltage (i.e., the voltage at which a device turns-on), their resistance, current capability, and leakage characteristics render them virtually useless at such low-voltages.

The problem with operating a power MOSFET at low gate voltages is that the transistor is highly resistive and loses energy to self heating as given by I²·R_{DS}·ton where ton is the time the transistor is conducting, I is its drain current and R_{DS} is its on-state drain-to-source resistance, or “on-resistance”. Specifically, a MOSFET's on-resistance is an inverse function of (V_{GS}−Vt), where (V_{GS}−Vt) describes how much the transistor's gate voltage V_{GS} exceeds its threshold voltage Vt. To avoid too much off-state leakage current over temperature, a MOSFET's threshold voltage is practically limited to around one-half volt minimum. At 0.9V gate bias, that means the transistor has only 0.4V voltage overdrive above its threshold, inadequate to fully enhance the transistor's conduction.

Power MOSFETs also suffer from high input capacitance. Input capacitance of a power MOSFET, measured in units of nano-Farads (or nF), comprises a combination of gate-to-source capacitance, gate-to-channel capacitance, and gate-to-drain capacitance, all of which depend on voltage. In power applications, power losses due to the charging and discharging of input capacitance are typically determined as a function of electrical charge rather than capacitance. By summing, i.e. integrating over time, the input current flowing during a switching transition, the total power needed to drive the MOSFET's gate can more readily be determined. This integral of current over time is a measure of charge, referred to as “gate charge” denoted mathematically as Q_{G} and represents the total charge needed to charge the device's input capacitance to a specific voltage. Because of the large gate width, the gate charge of a power MOSFET can be substantial, typically in the range of tens of nano-Coulombs (i.e. nC). The corresponding “switching” loss driving the device on and off with a gate bias V_{GS} at a frequency f, given by Q_{G}·V_{GS}·f, can at megahertz frequencies be comparable to conduction losses arising from device resistance.

Even more problematic, there is an intrinsic tradeoff between conduction and switching losses in power MOSFET's used in DC-to-DC power switching converters. Assuming fixed frequency operation with variable on-time given by duty factor D, the power loss in the MOSFET can in low-voltage applications be approximated by the equation:
P_{LOSS}≈I²·R_{DS}·D+Q_{G}·V_{GS}·f

Increasing the transistor's gate bias to reduce on resistance adversely impacts gate drive switching losses. Conversely reducing gate drive improves drive losses but increases resistance and conduction losses. Even attempts to optimize or improve a power MOSFET's design, layout, and fabrication involve compromises. For example, the gain of the transistor can be increased and its on-resistance for a given size device decreased by using a thinner gate oxide, but the input capacitance and gate charge Q_{G} will also increase in proportion. The tradeoff between on-resistance and gate drive losses limits the maximum efficiency of a converter, becoming increasingly severe at lower operating voltages. For example, the aforementioned tradeoff prevents Lilon-powered switching converters from operating at frequencies over a few megahertz, not because they can't operate, but because their efficiency becomes too low. In one-cell NiMH applications at 0.9V, the devices may not switch at all.

As an alternative to the power MOSFET, one device that may hold promise for such 0.9V-switching applications is the MESFET, or metal-epitaxial-semiconductor field effect transistor as shown in FIG. 1. Unlike the MOSFET which has an insulated gate, and conducts current by electrically inverting the surface to form a conductive N- or P-channel, the MESFET employs a Schottky rectifier as a gate, modulating the depletion region of the Schottky to control the drain current, preferably without forward biasing or avalanching the Schottky diode during operation. A transition from minimum drain current to maximum drain current can occur in less than one volt change in gate bias, far less than the voltage needed to operate the MOSFET for low-resistance power applications. Its ability to operate at low gate-drive voltages makes the MESFET potentially attractive as a power device, but also introduces certain yet unresolved challenges. Of these challenges, the most significant problem is commercially available MESFETs are limited to the normally-on, or depletion-mode type. Normally-on type switches are unfortunately not useful for power switching applications.

MESFET Device & Fabrication

In the example shown the MESFET is made of a wide-bandgap or compound semiconductor such as gallium-arsenide (GaAs), advantageous for its low-leakage Schottky characteristic needed for forming its gate and for its high-speed switching capability. Other wide-bandgap or compound semiconductor materials can include indium-phosphide (InP), various III-V compounds, various II-VI compounds, silicon carbide (SiC), or semiconducting diamond. As an alternative to wide bandgap materials, silicon may be used, but silicon's Schottky leakage characteristic is generally not attractive for power applications, especially when operation over temperature and self-heating are considered. Moreover, many wide-bandgap and compound semiconductor materials are better suited for high frequency operation due to their high carrier mobility and high carrier saturation velocities—material properties that improves the aforementioned resistance—gate charge tradeoff. Frequently the active MESFET device is formed in a deposited epitaxial layer that has different resistivity than the substrate on which it is deposited. In other instances the epitaxial layer may comprise a completely different material and crystalline structure than the substrate.

FIG. 1 illustrates a three-dimensional perspective of a prior art GaAs MESFET comprising epitaxially grown GaAs mesa 12 formed on semi-insulating (SI-GaAs) substrate wafer 11. While theoretically, mesa 12 could be made in either P-type or N-type material, in practice only N-type material is convenient for manufacturing and is commercially available while P-type material is not. Most of mesa 12 comprises lightly-doped to moderately-doped material N—GaAs layer 13 except for the top layer which is epitaxially grown as heavily doped N+ layer 14.

A trench 16 is etched into mesa 12 to a depth greater than N+ layer 14. This trench bisects the mesa into two regions, one mesa portion comprising the MESFET's source, the other comprising its drain. Metal 15 formed in trench 16 forms the MESFET's Schottky gate. A second type of metal used for contacting the N+ regions 14 and for contacting the Schottky metal 15 is not shown in this drawing. Mesa 12 is formed by masking and etching the GaAs epitaxial layer 13 and 14 which otherwise would cover substrate 11 in its entirety.

The device is fabricated in a GaAs mesa formed by etching away the GaAs epitaxial layer surrounding it by a chemical or plasma mesa etch. The mesa etch is required to isolate the device from other devices since GaAs and other III-V or binary-element crystals do not readily form insulating dielectrics through thermal oxidation. In some crystals, high temperature processing like thermal oxidation also causes dopant segregation, redistribution, and even stoichiometric changes in the crystal itself. The mesa etch is expensive both in its processing time needed to remove micron thick semiconductor layers, and in reducing useful active wafer area

In silicon processes a shallow N+ layer is normally introduced through ion implantation or high-temperature “predeposition”, but in some materials the only way to achieve high dopant concentrations is through epitaxial growth. In GaAs MESFET fabrication, this task is achieved by epitaxially depositing N-type layer GaAs 13 followed by deposition of N+ layer 14, generally all performed in the same epitaxy chamber.

At the onset of the epitaxial deposition process the GaAs doping may comprise alternating layers of varying stoichiometry to form a sandwich structure of varying work functions, concentrations, or of P-N junctions. The sandwich structure impedes carrier transport across the sandwich layer, to minimize leakage through the substrate, especially when the substrate is only semi-insulating. In some instances the interfacial buffer layer may also provide stress relief if the deposited epitaxial layer has a different crystalline structure than the substrate (e.g., for silicon on sapphire deposition). Stress relief is especially important in cases where the epitaxial layer has a different crystal lattice and atomic periodicity or a significantly different temperature coefficient of expansion that the silicon substrate.

To those skilled in the art it will be understood that the forgoing discussion illustrating a GaAs MESFET fabricated using a GaAs epitaxial layer deposited atop of GaAs substrate may be adjusted to employ other semiconductor epitaxial materials and alternative substrate materials. Furthermore for the sake of simplicity the presence of interfacial layers at the epitaxy-substrate interface are intentionally not shown except in specific examples discussing their properties.

FIG. 2 illustrates a prior art GaAs MESFET of FIG. 1 in greater detail. In side view, FIG. 2A illustrates cross section 20 illustrating trench 16 covered by Schottky metal 15 etched into mesa 12 through N+ layer 14 and into N− GaAs layer 13. Metal contacts 17, 18, and 19 are used to contact the source, gate, and drain respectively. Plan view 30 illustrates the edges defining the mesa 12, the Schottky metal 15, and the trench 16. The channel length of the device is defined by the trench 16 opening contacting, i.e. touching, Schottky metal 15. In conventional structures, Schottky metal 15 has a cross-sectional dimension smaller than trench 16 and is centered within said trench. For the sake of discussion, the gap between Schottky metal 16 and the edge of trench 16 shall be referred to as drift length L_{D}. In the prior art structure shown, the drift length L_{D} is equal on both sides of gate 15 since Schottky metal 15 is centered within the trench.

FIG. 3 illustrates the steps in fabrication of prior art MESFET device 40. In FIG. 3A, epitaxial layers 43 and 44 are sequentially deposited via epitaxy atop semi-insulating GaAs wafer 41. In typical devices, N− GaAs layer is lightly or moderately doped with doping concentrations ranging from 1 E14 cm⁻³ to 4E17 cm⁻³ with a thickness of 1 to 3 micrometers. N+ layer 44 is heavily doped concentrations ranging from 7E1 cm⁻³ to 1E20 cm⁻³ with a thickness of 0.5 to 1 micrometers. Transition layer 42 is formed by varying the epitaxial deposition conditions to minimize leakage and in some instances to minimize mechanical stress between the epitaxial layer and the substrate.

In FIG. 3B, trench 45 is photolithographically defined and etched to a depth greater than N+ layer 44, typically 1 to 2 micrometers. In prior art devices, the vertical depth of trench 45 comprises a small fraction of the total thickness of epitaxial layer 43. The control of the trench depth impacts the transconductance, resistance, and threshold voltage of the device. For the sake of clarity, transition layer 42 is not shown in this or the subsequent drawings.

In FIG. 3C, a Schottky barrier metal is deposited, photolithographically patterned, and etched to form gate metal 46. Photolithographic patterning of the MESFET's Schottky gate may be performed using direct etching or lift-off etching techniques. In direct etching the Schottky barrier gate material to be patterned is first deposited onto the wafer, then the wafer is coated with photoresist (a light sensitive organic emulsion), patterned through a photomask, and the exposed areas of the Schottky gate metal material (not covered by photoresist) is subsequently removed by wet chemical or plasma (dry) etching. In lift-off etching, photoresist is first coated on the wafer and photo-masked to produce exposed semiconductor areas and those protected by un-removed photoresist. The Schottky gate metal is then deposited (at low temperatures by sputtering or evaporation). After gate metal deposition, the photoresist is removed lifting off the metal sitting atop it, leaving the MESFET's gate metal intact. Regardless which method is employed the resulting cross section remains the same, as shown in FIG. 3C.

In FIG. 3D, a layer of interconnect metallization 47, typically gold, is deposited, then in FIG. 3E, the gold layer metal layer is patterned and etched using direct etch methods to form gate electrode 48G, source electrode 48S, and drain electrode 48D. Alternatively, photolithographic patterning of the MESFET's interconnect metal may be performed using the aforementioned lift-off etching techniques.

Finally in FIG. 3F the entire device is isolated by photolithographic masking and etching to form an isolated mesa. Because the device utilizes only a single metallization layer for interconnection, the geometric layout of the device remains limited compared to devices used in silicon integrated circuits.

FIG. 4 illustrates the influence of the process design parameters of the electrical behavior of the MESFET. In FIG. 4A, device 50 comprises substrate 51, N− epitaxial layer 52, N+ epitaxial layer 53, trench 54 and gate metal 55. The total epitaxial layer thickness xₑₚᵢ comprises the thickness of both layers 52 and 53. The trench 54 has a depth xₜ with a resulting thickness for the conducting channel x_{ch} where:
x_{ch}=xₑₚᵢ−xₜ

and where the channel thickness x_{ch} affects the device's on-state current and resistance, its threshold voltage, and its off state leakage current.

For conventional prior-art GaAs MESFETs, trench gate 54 is only slightly deeper than the N+ layer. In such a construction, the zero-bias depletion region resulting from the junction barrier between Schottky gate metal 55 and N—GaAs layer 52 is insufficient to reach through layer 52 to semi-insulating substrate 51. The resulting device is referred to as a “depletion mode” transistor since it is in a conductive state even when its gate is shorted to its source, i.e. when V_{GS}=0, as shown by curve 60 labeled I_{DSS} in FIG. 4B.

The term depletion mode, often used to describe normally-on MOSFETs, actually is borrowed from the vernacular of junction field effect transistors (JFETs), which behave as normally “on” devices, and whose conductivity is varied through the modulation of the gate P-N junction's depletion region. In this regard MESFETs operate very similarly to JFETs, as a normally-on type device, where drain-to-source conductivity is modulated by varying the width of the reversed biased depletion region of the gate.

Operation of a MESFET may therefore comprise reverse biasing of the MESFET gate to increase the gate depletion region width so as to pinch-off the channel and decrease drain current; or alternatively by forward biasing the MESFET gate to decrease the gate depletion width, allowing more current to flow. Ideally gate current should remain low or near zero, meaning the gate should not be forward biased to a voltage where diode conduction ensues, nor should the gate be reversed biased to such a large potential that significant impact ionization or avalanche breakdown results. So unlike a MOSFET which utilizes an insulated gate input that prevents gate conduction over a wide range of positive and negative gate potentials, the MESFET's Schottky gate is limited to a more narrow operating voltage range.

The impact of changing a MESFET's gate potential on its drain current is illustrated in FIG. 4B for both forward biased (V_{GS}>0) and reverse biased (V_{GS}<0) gate potentials.

By forward biasing the Schottky gate to the maximum positive voltage without conducting substantial gate conduction current, i.e. for V_{GS} around 0.5 to 0.6 volts, the minimum possible on-resistance and maximum device current for the MESFET is illustrated in curve 61. The maximum current is referred to as I_{Dmax}. Curve 62 illustrates the condition when the MESFET's Schottky gate is reverse-biased with respect to N—GaAs layer 52. Under reverse bias conditions, the gate depletion region reaches deeper into the epitaxial layer reducing the cross sectional area conducting channel current, reducing the current and increasing on-resistance. In the case where the gate voltage is set to the maximum reverse biased potential before the onset of avalanche of the gate Schottky diode, this minimum drain current condition is herein referred to as I_{Dmin}.

Depending on the doping of the epitaxial layer 52, the gate metal used, and the net epitaxial thickness x_{ch}, the depletion region may not reach through the epitaxial layer even under reverse gate bias. If so, the minimum current in the device I_{Dmin} is not zero (as depicted in the example FIG. 4B). In prior art devices as shown, the zero-biased gate condition (i.e. when V_{GS}=0) results in a current I_{DSS} well above zero, so MESFET comprises a depletion mode device

In the event trench 54 is etched slightly deeper such that the reverse bias of gate 55 fully depletes the epitaxial layer under the trench gate, the magnitude of I_{Dmin} is reduced but because I_{DSS} is not “zero”, the device remains a depletion mode device, not suitable for use as a power switch.

Comparing Enhancement & Depletion Mode MESFET Characteristics

Accordingly, prior art MESFETs have almost exclusively been used only for radio frequency (RF) applications like an RF switch used to multiplex an antenna in a cell phone between its transmitter and receiver circuitry. Used as an RF switch, minimizing a MESFET's “small signal” AC capacitance is more important than improving its on resistance or saturation current. Since RF circuits generally comprise small-signal non-power applications, depletion mode MESFET devices are commonly available radio frequency components today. Because enhancement mode device characteristics are not required in RF applications, no commercial impetus existed to address the various technical issues prohibiting the manufacture of reliable normally-off MESFETs. As a result enhancement-mode MESFETs were never commercialized.

So the need for an enhancement-mode MESFET with low I_{GSS} (off-state) leakage is mandatory for adapting a MESFET for power switch applications.

As a comparison to the prior-art depletion mode MESFET characteristics shown in FIG. 4B, FIG. 4C illustrates the hypothetical characteristics of an enhancement mode MESFET. Specifically curve 65 illustrates the transistor's drain current at a zero-volt gate bias should be very low, having an I_{DSS} value near zero (e.g. under 1 μA). Curve 67 illustrates the drain leakage may be further depressed, but only slightly, by the application of reverse-biased gate bias. Curve 66 illustrates the enhanced conduction of the MESFET under a condition of positive gate bias. When the gate potential is biased to the maximum positive potential before the onset on forward biased conduction current in the Schottky gate, the MESFET's drain current reaches its maximum value I_{Dmax}, and its minimum on-resistance R_{DSmin}.

FIG. 4D illustrates the conduction characteristics of the gate Schottky diode. The maximum forward bias of Schottky gate 55 is determined by its onset of conduction, typically at 0.5V to 0.7V. To minimize DC drive losses, the gate should be forward biased ideally with less than one milliamp of gate conduction current, and ideally with gate currents in the microampere range. Furthermore, the maximum reverse bias of Schottky gate 55 is determined by its avalanche breakdown to N+ layer 53. The gate should not be driven into avalanche or device damage may result. So unlike a MOSFET's wide positive and negative gate voltage capability, the MESFET is limited to a voltage V_{F} in the forward biased direction and to a breakdown voltage BV_{GD} in its reverse direction.

FIG. 4E illustrates the impact of the net epitaxial thickness x_{ch} under the gate. As shown by curve 70 for V_{GS}=0, thicker dimensions mean that the epitaxial layer cannot be pinched off at zero volts. Such normally-on devices and are by definition depletion mode. Any epitaxial channel thinner than some critical value (see dashed line 73) represents a device that is shut off at a zero gate bias condition and by definition constitutes an enhancement mode device.

Curve 71 illustrates an increase in conduction current resulting from slightly forward biasing the gate. In contrast, curve 72 illustrates a decrease in drain current from reverse biasing of the gate. For devices with epi thicknesses above some critical thickness represented by vertical dashed line 74, the device cannot be shut off even with reverse bias. In every bias condition, thinner channels conduct less current than thicker ones.

FIG. 4F illustrates three different MESFETs' drain currents as a function of positive and negative gate bias. In enhancement mode device A, curve 75 illustrates a near zero off state leakage I_{DSSA} and a maximum current limited by the maximum positive gate voltage before the onset of Schottky conduction (illustrated by line 78). Such a device has the electrical characteristics of a normally off switch, useful in power applications. In device B, the device is conducting for V_{GS}=0, i.e. I_{DSSB}>0, but can be shut off by applying a reverse bias to its gate. Such devices, while not generally useful for power switch applications, are commonly used for RF switches in cell phones. Device C typical of the prior art (illustrated by line 77) is a device with the thickest epitaxial layer and cannot be shutoff even if the maximum negative bias shown by dashed line 79 is applied. While such device may still be used in small-signal circuit applications (such as an amplifier or gain element), they are not useful as a power switch since they cannot be shut off, even with a high negative gate bias.

FIG. 5A illustrates the bias conditions needed to turn off MESFET switch 80, including a gate-to-source short, i.e., where V_{GS}=0, and where depletion region 81 pinches off epitaxial layer 83. The highest electrical field point 82 occurs at the edge of the trench where the gate and the drain meet, at the Schottky gate edge (point 84), or otherwise along the surface in between these two points. As shown in FIG. 5B, the onset of avalanche at a higher drain voltage leads to a rapid rise in current. The combination of high electric fields and high current densities in the vicinity of point 82 leads to localized carrier generation, avalanche, and hot carriers that can destroy the device. The MESFET in its prior art form is therefore not suitable for power switching applications because of its inability to survive even temporary over-voltage conditions.

Aside from certain fundamental frailties intrinsic to the device's present construction, commercially available MESFETs have other design limitations that further degrade their avalanche ruggedness. In prior art device 90 shown by the plan view in FIG. 6A, Schottky gate metal 93, trench 92, and gate metal 94G, divide and separate drain 94D (and drain pad opening 98D) from source 94S (with corresponding pad opening 98S). The serpentine gate (biased via pad opening 98G) terminates at two edges of the etched mesa defined by photomask and mesa etch layer 91. Mesa etch layer 91 is not the same as trench 92, since the mesa etch is much deeper, removing the entire thickness of the epitaxial layer down to the semi-insulating substrate.

Since the trench and Schottky gate extends to the edges of the mesa, the electric field at the drain-to-gate interface is especially high along the surface at points A and B as shown. Due to surface state charges, the origin of leakage current and the onset of avalanche will be most severe at the device surfaces, especially at the mesa edge at points A and B.

These locations will be especially fragile to any electrical abuse as illustrated in the three-dimensional illustration of device 99 in FIG. 6B, where trench 92 and gate metal 93 exhibit a high electric field along the etch mesa surface of the device, especially at point A at the mesa surface. Their fragility is further exacerbated by their limited area, causing a localized rapid increase in temperature at these points at the onset of avalanche before other areas of the device even begin to avalanche.

What is needed is a MESFET capable of normally-off characteristics, low on-state resistance, low gate charge, and robust avalanche characteristics.

### SUMMARY OF INVENTION

One aspect of the present invention provides a MESFET device with improved avalanche capability. This is accomplished by eliminating the high-field point between gate and drain along the device's etched mesa surface by enclosing the drain concentrically by both gate and source regions. In such designs, no Schottky junctions are located touching, abutting or overlapping the mesa etched surface. For a typical example, a MESFET is fabricated as a square drain region surrounded by a ring-shaped Schottky gate. The gate is surrounded, in turn by a source region so that no Schottky junction or interface is exposed to the MESFET's outer edge. The source forms the outer edge of the MESFET. Since the source is generally biased to the same potential as the package leadframe on which the die is mounted, and since no voltage differential exists between this outer die edge and its surroundings, there is no reason to perform a mesa etch. Instead the die separation through sawing is adequate to isolate devices without the need for an expensive and time consuming deep-mesa etch process common to radio frequency (RF) MESFETs.

Numerous variations of this design are possible. Thus, the drain may be square, rectangular, interdigitated or otherwise shaped and the source may fully or partially surround the Schottky gate. The MESFET is preferably made with the Schottky gate located within a trench where said trench is etched sufficiently deep to result in a normally off characteristic having low drain leakage current whenever V_{GS}=0, i.e. whenever the gate is electrically shorted to the source.

Another aspect of the present invention provides a MESFET device that reduces MESFET gate leakage and impact ionization by eliminating the risk of the Schottky barrier touching or nearly touching the trench gate sidewall as a result of photomask misalignment. For a MESFET of this type, a trench gate is formed in a mesa of an N—GaAs epitaxial layer. The epitaxial layer is formed on top of a semi-insulating substrate. N+ regions on either side of the trench comprise the MESFET's source and drain regions. Each has its own metal contact. Schottky metal is positioned inside of the trench with another metal contact. A sidewall spacer lines the edges of the trench preventing the Schottky metal from touching the trench sidewalls. Compared to conventional MESFET structures, this sidewall spacer trench gated MESFET is unique in its low electric field, minimal leakage current along the trench sidewall, and insensitivity to photomask misalignment. It also prevents metal from ever coming in contact with the trench sidewall, eliminating the risk of unwanted metal residues on the trench sidewall.

Another aspect of the present invention provides several methods for preventing MESFET damage in avalanche. For one of these methods, a voltage clamp is used to limit the maximum drain-to-source voltage of a MESFET. The voltage clamp is implemented as a Zener diode connected in parallel with the MESFET where the breakdown of Zener diode is less than the breakdown voltage of the MESFET in its off state. The MESFET and Zener diode are preferably formed as separate die included in a single package. Fast voltage clamping may be achieved by paralleling the Zener diode and MESFET through wire bonds, thereby minimizing interdevice inductance, ringing, and voltage overshoot. To parallel the devices, the MESFET's drain electrode is connected to the Zener cathode and the MESFET's source electrode is connected to the Zener anode. The Zener clamp allows the MESFET to operate asymmetrically with respect to drain voltages, blocking current in one direction up to the Zener breakdown voltage BV_{Z}, and conducting current through the Zener in the opposite polarity thereby limiting the maximum reverse voltage to the forward diode voltage V_{f} of the Zener.

In an alternative embodiment, two back-to-back series-connected Zener diodes together form a voltage clamp in parallel with the MESFET's source-to-drain terminals. The back-to-back Zener diodes may be connected in series with either a common anode or a common cathode connection, and protect the MESFET's drain-to-source terminals in either polarity operation. In a preferred embodiment each diode should have the same Zener breakdown voltage. The symmetric Zener clamp allows the MESFET to operate symmetrically with respect to drain voltages, blocking current in either direction up to the Zener breakdown voltage BV_{Z}. In another embodiment the two Zener diodes are fabricated in a single silicon die, packaged in a single package with a power MESFET, and connected to said MESFET using bond wires.

Another method to achieve MESFET voltage clamping is to employ a series of forward biased P-N diodes in parallel to the MESFET's drain-to-source terminals. This approach is particularly important when no Zener diode is available. In circuits of this type, any number of similar or identical P-N diodes are connected in series with the whole series wired in parallel to the drain-to-source terminals of a MESFET. Configured in a totem-pole arrangement, i.e. anode to cathode connected, the series connected diodes all forward bias in the same polarity. Voltage clamping is achieved by forward biasing the diode stack to limit the MESFET's maximum drain-to-source voltage. So long as the number of diodes “n” times the forward voltage V_{F} of any one diode is less than the avalanche voltage of the MESFET's drain to gate diode (and therefore less than the drain-to-source avalanche of the MESFET), then the MESFET is voltage clamp protected in that polarity, i.e. (n-V_{F})<BV_{DSS}. The forward-biased clamp allows the MESFET to operate asymmetrically with respect to drain voltages, blocking current in one direction up to the series forward biased voltage (n·V_{F}), but does not protect in the opposite polarity.

A modification to this type of voltage clamp, adds a diode in parallel to (but oriented in the opposite polarity to) the series of forward biased diodes. This “anti-parallel” diode has no effect on the forward blocking characteristics of the diode series. In the reverse direction, the anti-parallel diode forward biases, and thereby limits the maximum reverse voltage to one V_{D}. This voltage, while too low to use in normal reverse blocking operation, allows the MESFET to operate with reverse diode conduction. The combination of the series-connected forward-bias and the single anti-parallel clamp allows the MESFET to operate asymmetrically with respect to drain voltages, blocking current in one direction up to the sum of the forward biased diode (n·V_{F}), and conducting current through the single diode in the opposite polarity thereby limiting the maximum reverse voltage to the forward diode voltage V_{f} of the diode.

Another method to achieve MESFET voltage clamping is to employ two strings of series connected forward biased P-N diodes; one in parallel to the MESFET's drain-to-source terminals, the other one antiparallel to the MESFET's drain-to-source terminals. This approach is particularly important when bidirectional blocking is needed and no Zener diode is available. In circuits of this type, any number of similar or identical P-N diodes is connected in series to form the diode clamp strings. This type of clamp allows the MESFET to operate symmetrically with respect to drain voltages, blocking current in either direction up to the forward voltage of the diode string (n·V_{F}).

### DESCRIPTION OF FIGURES

FIG. 1 Three-dimensional illustration of prior-art conventional GaAs MESFET.

FIG. 2 Illustration of conventional prior-art GaAs MESFET (A) cross section (B) plan view.

FIG. 3 Manufacturing process sequence for prior-art conventional GaAs MESFET (A) epitaxial deposition (B) trench etch (C) Schottky gate deposition (D) metal deposition (E) metal patterning (F) mesa etch.

FIG. 4 Comparison of depletion mode and enhancement mode MESFET devices (A) cross section (B) depletion-mode I_{D} VS. V_{DS} family of curves (C) enhancement-mode I_{D} vs. V_{DS} family of curves (D) MESFET gate characteristics (E) effect of trench depth on threshold (F) drain current of different threshold voltage MESFETs.

FIG. 5 Avalanche breakdown of prior art MESFET (A) cross section illustrating avalanche mechanism (B) I-V avalanche characteristics for depletion and enhancement mode MESFETs.

FIG. 6 Layout of prior art conventional MESFET (A) plan view (B) 3-D projection.

FIG. 7 Illustration of enclosed MESFET for improved avalanche characteristics (A) plan view of square drain device (B) plan view of rectangular drain device (C) plan view of serpentine drain device (D) cross section of serpentine device (E) plan view of source enclosed device.

FIG. 8 Cross section of sidewall-spacer MESFET.

FIG. 9 Fabrication of sidewall spacer MESFET (A) trench gate etch (B) sidewall oxide deposition (C) Oxide etchback & spacer formation (D) Schottky metal deposition (E) Schottky gate mask and etch (F) Interconnect metal deposition (prior to masking & etch).

FIG. 10 Cross sections of various mesa etch methods (A) conventional MESFET, but without mesa etch (B) conventional prior-art MESFET with mesa etch (C) surrounding source MESFET.

FIG. 11 Cross section of improved Schottky gate MESFET (A) non-conformal gate (B) oxide sidewall and sandwich.

FIG. 12 Zener-clamped MESFET (A) schematic (B) side view (C) plan view (D) packaging example.

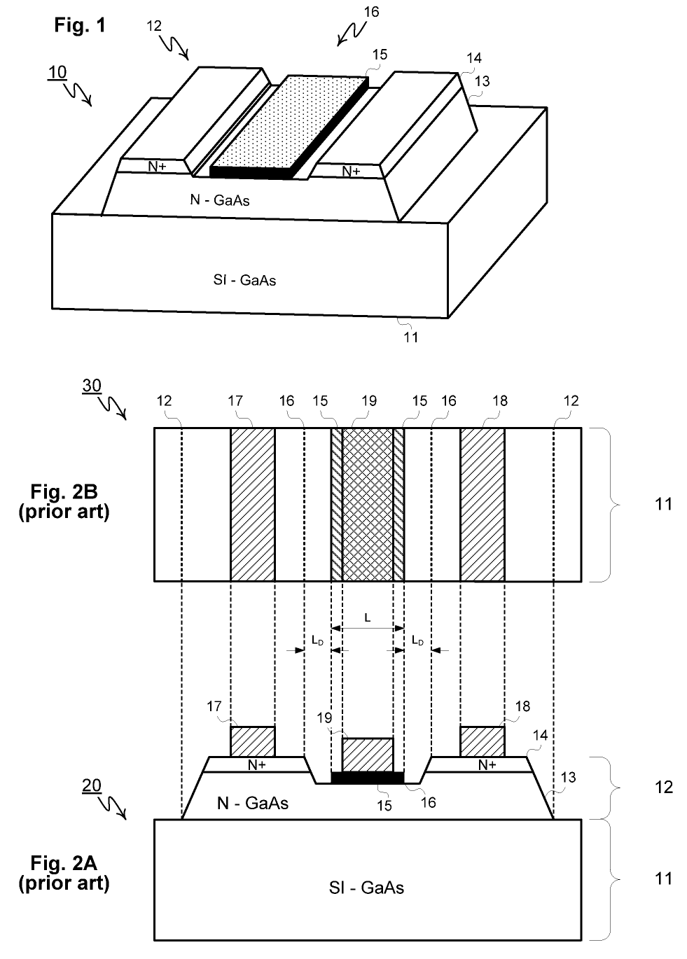

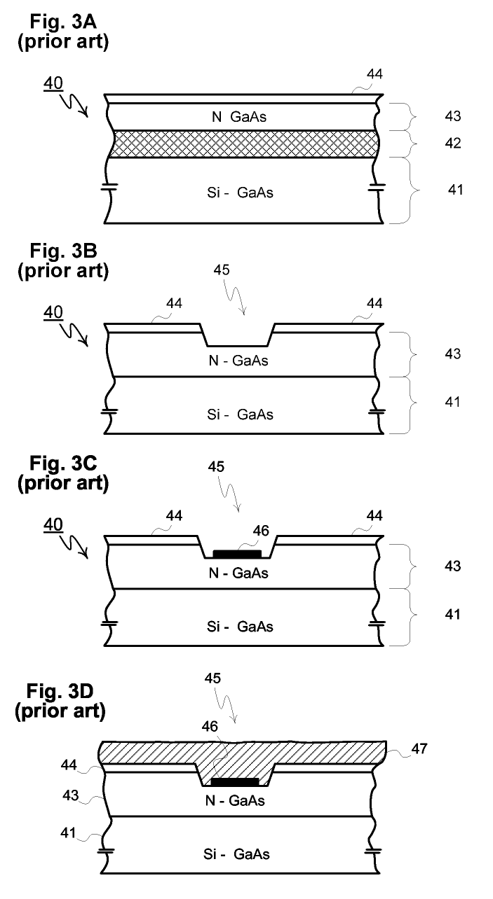

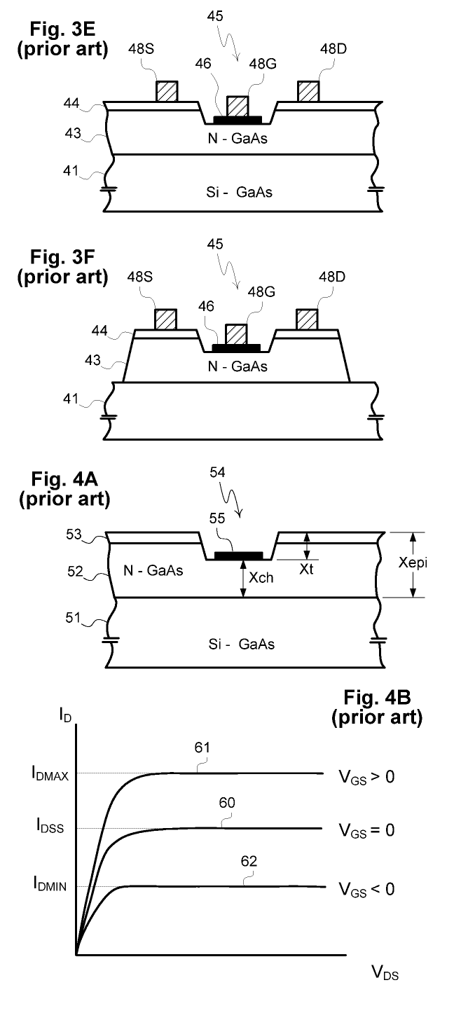

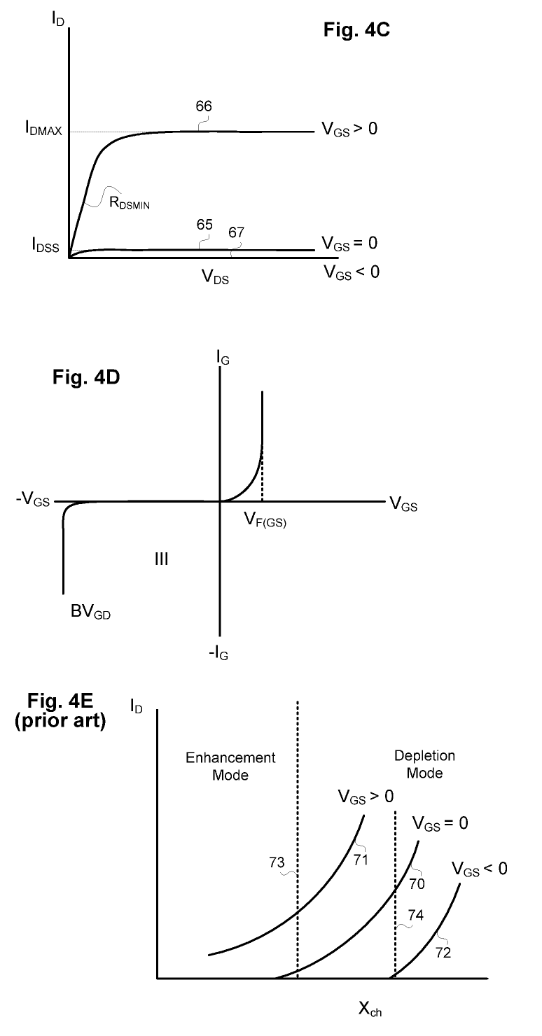

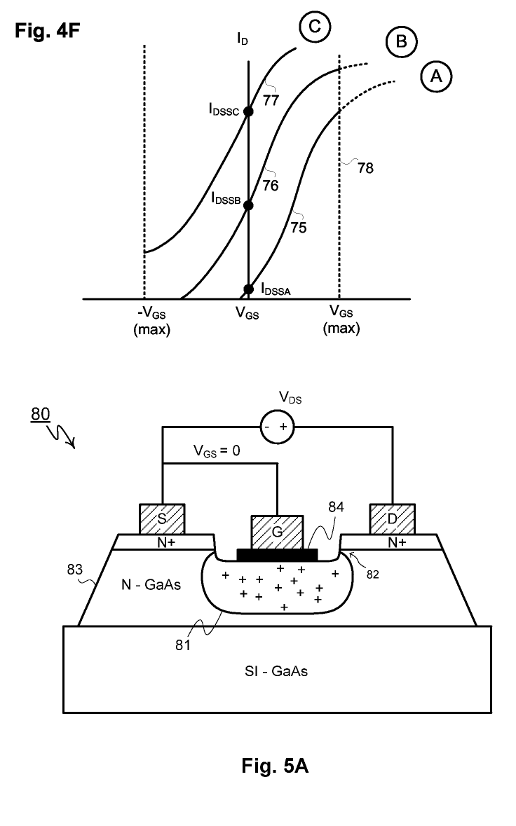

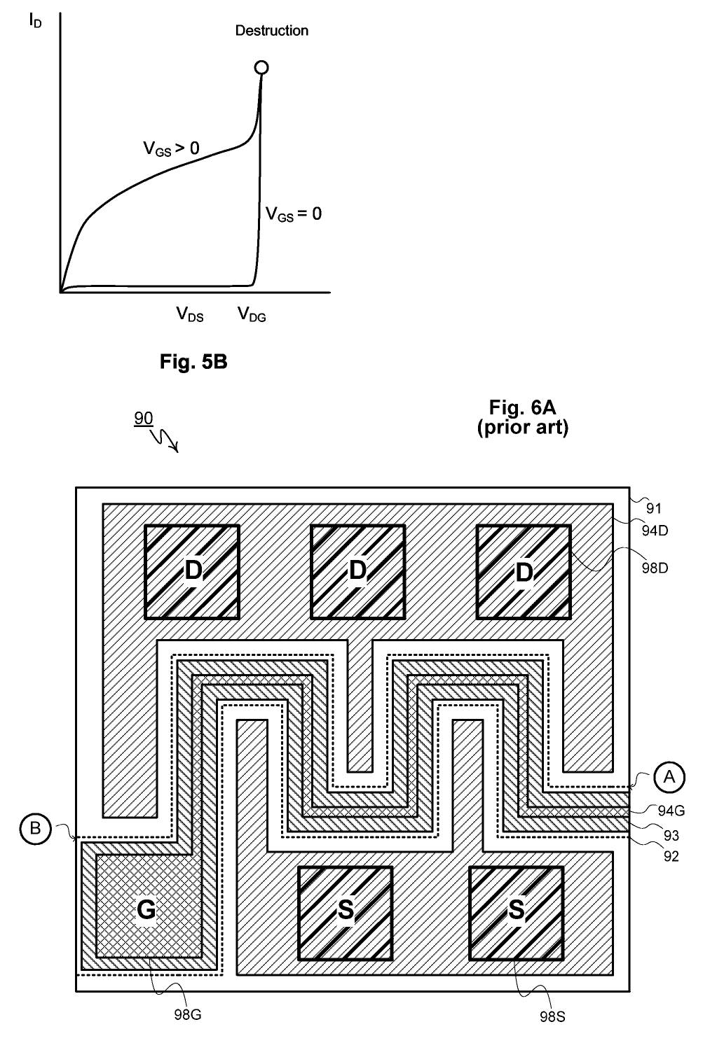

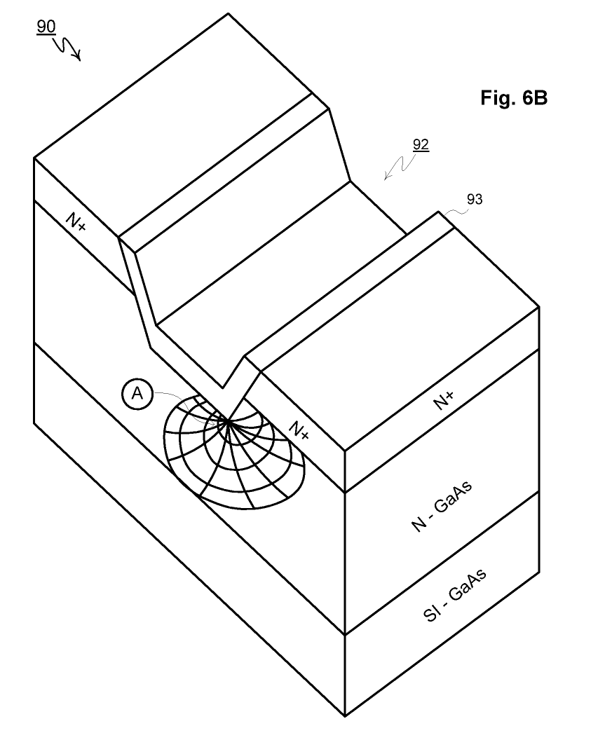

### DESCRIPTION OF INVENTION

Adapting MESFETs for efficient, robust, and reliable operation in switching power supplies requires innovations and inventive matter regarding both their fabrication and their use. These innovations are described in the related applications previously identified. The design and fabrication of power MESFETs for robust operation and rugged avalanche characteristics, especially for use in switching converters, requires inventive matter, which is the main subject of this invention disclosure.

Specifically, to improve the ruggedness and avalanche capability of a power MESFET, three issues must be addressed in its design and fabrication. The intrinsic weaknesses in present day MESFETs include edge breakdown effects, surface breakdown effects, and lack of a low-impedance voltage clamp in the unipolar MESFET structure itself. Remedies for each of these issues may be applied individually, or in combination, to improve the avalanche ruggedness and robustness of a MESFET to a level suitable for power applications.

Eliminating MESFET Edge Breakdown

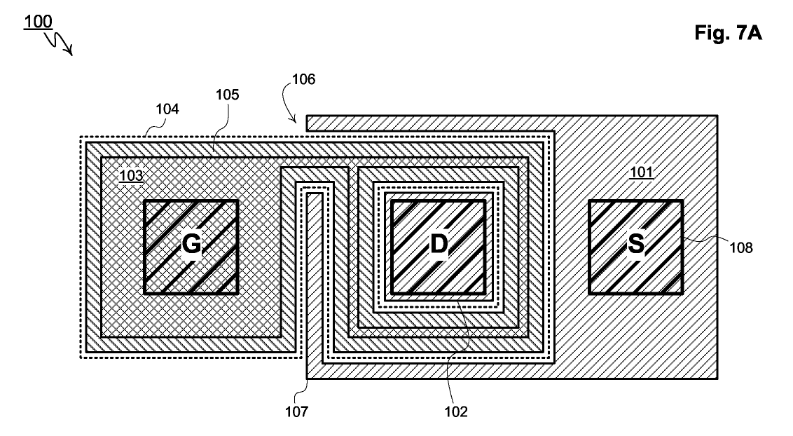

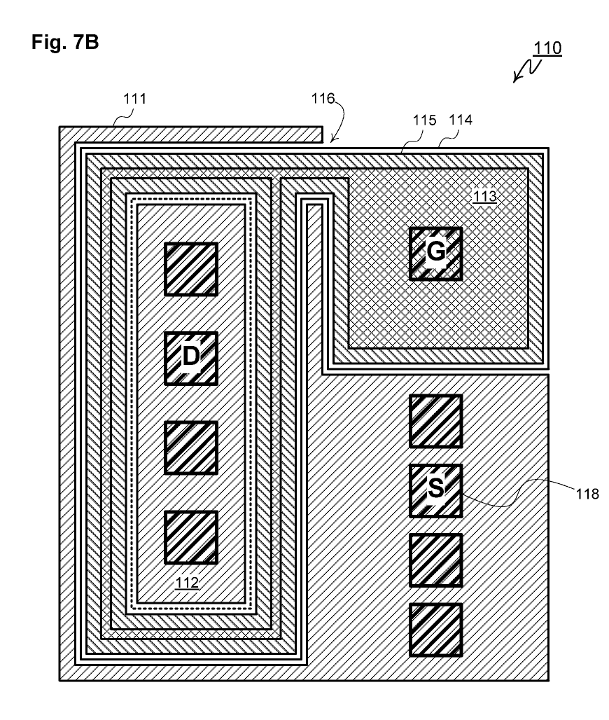

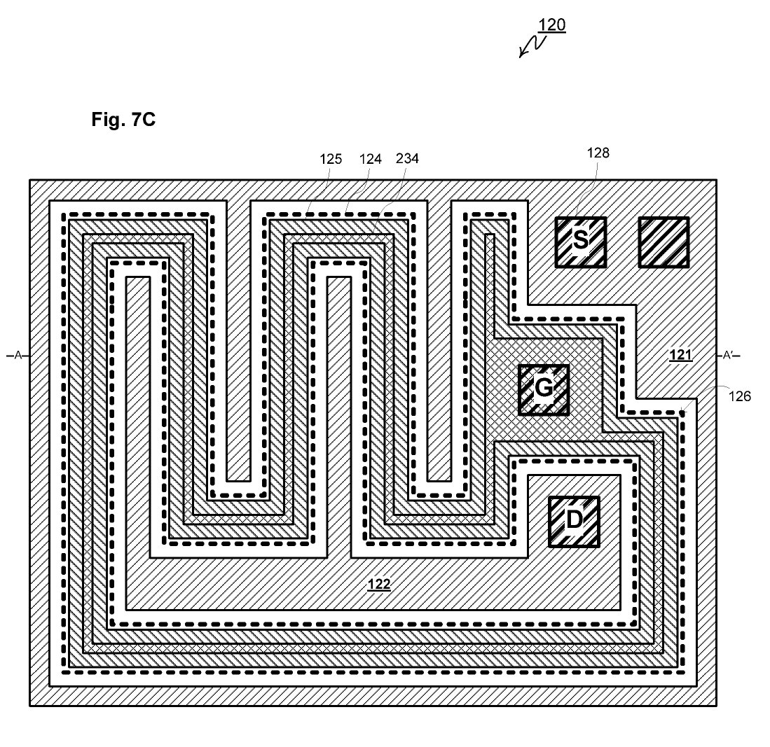

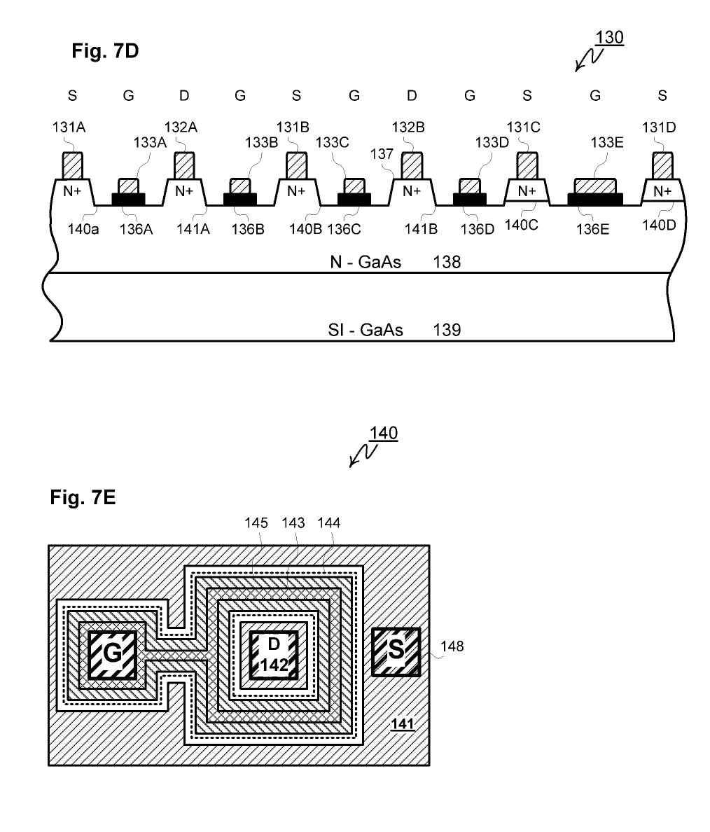

FIG. 7 illustrates plan views of several MESFET devices with improved avalanche capability. In each inventive example the high-field point between gate and drain along the device's etched mesa surface has been eliminated by enclosing the drain concentrically by both gate and source regions. In such designs, no Schottky junctions are located touching, abutting or overlapping the mesa etched surface.

Furthermore, it will be shown by employing concentric-like design, the source can constitute the outer edge of the device, entirely enclosing the MESFET. Since the source is generally biased to the same potential as the package leadframe on which the die is mounted, and since no voltage differential exists between this outer die edge and its surroundings, there is no reason to even perform a mesa etch. Instead the die separation through sawing is adequate to isolate devices without the need for an expensive and time consuming deep-mesa etch process common to radio frequency (RF) MESFETs.

For example, in FIG. 7A, MESFET 100 comprises a square-drain-centric design, where drain contact metal 102 is surrounded by a ring-shaped gate comprising Schottky-metal 105; trench region 104; and gate metal interconnect 103. The entire device is surrounded by source region and contacted by metal 101, so that no Schottky junction or interface is exposed to the device's outer edge. Source metal 101 completely surrounds gate 105 and drain 102 with the extension of 106 and 107 source metals facing all four sides of drain 102, except where the gate pad is connected. Typically source, gate, and drain interconnect metal comprise the same material (e.g. gold). Source, gate and drain regions are electrically contacted through pad openings 108.

MESFET 110 in FIG. 7B illustrates an elongated version of concentric device 100 with rectangular drain metal 112 surrounded by annular shaped Schottky gate metal 115, trench 114, and interconnect metal 113. Source metal 111 completely surrounds gate 115 and drain 112 including metal finger 116 facing all drain edges. Typically source, gate, and drain interconnect metal comprise the same material (e.g. gold). Source, gate and drain regions are electrically contacted through multiple pad openings 118 as needed for multiple bond-wire packaging.

MESFET 120 in FIG. 7C illustrates a concentric interdigitated multi-finger with rectangular drain metal 122 surrounded by a ring of Schottky gate metal 125, trench 124, and interconnect metal 123. The MESFET's gate ring 125 and drain 122 are surrounded on all sides by source metal 121. Typically source, gate, and drain interconnect metal comprise the same material (e.g. gold). Source, gate and drain regions are electrically contacted through multiple pad openings 128 as needed for multiple bond-wire packaging, and may be staggered to improve bonding angles. The gate enclosing the drain need not be a strictly rectangular shape and may also have staggered and stair stepped dimensions like that of location 126, so long that it surrounds drain 122.

FIG. 7D is a cross sectional view 130 of device 120, transected through the gate pad region lengthwise along the line A-A′. The device comprises semi-insulating substrate 139, epitaxial layer 138 with a top N+ layer cut into drain and source regions by the trench gate. N+ source regions 140A, 140B, and 140C contacted by source metal 131A, 131B, and 131C respectively surround drain regions 141A and 141B, contacted by drain metal 132A and 132B. Source regions 140C and 140D (with metal contacts 131C and 131D) also surround wide trench gate-pad region 133E sitting atop Schottky metal 136E. Gate metal 133A through 133D connects to 133E (not shown in cross section) and connects Schottky gates 136A through 133D respectively. No drain-to-Schottky junction is exposed to the mesa edge or die edge. The edge of a die is therefore defined by the saw cut and not by an etched mesa.

In FIG. 7E, MESFET 140 comprises a square-drain-centric design, where drain contact metal 142 is surrounded by a ring-shaped gate comprising Schottky-metal 145; trench region 144; and gate metal interconnect 143. The entire device is surrounded by source region and contacted by metal 141, so that no Schottky junction or interface is exposed to the device's outer edge. Source metal 141 completely surrounds gate 145 and drain 142 on all sides, with the outer edge of source metal 141 parallel to the die edges. Source, gate and drain regions are electrically contacted through pad openings 148.

Eliminating MESFET Surface Avalanche

Eliminating edge-related avalanche breakdown and leakage through concentric die geometries may eliminate “hot spots” but does little to suppress gate leakage or field plate induced avalanche in the proximity of the gate.

The problem with the MESFET gate is two-fold; first, the Schottky metal exhibits a voltage related leakage due to a phenomenon known as barrier lowering, and second, the two-dimensional shape of the trench gate and its relatively acute angle and sharp edges can exacerbate electric fields and induce hot carrier generation and impact ionization, precursors to the onset of avalanche. Since impact ionization tends to arise from concentrated electric fields and weak spots near point defects in the etched GaAs crystal, the avalanche can occur non-uniformly.

If sufficient avalanche current is conducted in a small region, excessive temperatures may develop and damage the device, especially near the Schottky gate. This sensitivity to hot spot formation and barrier lowering is greatest where the Schottky gate faces the drain on the trench sidewall and at the trench top and bottom corners.

The inability of the MESFET to survive localized avalanche current concentration is further exacerbated by the poor thermal resistance of GaAs, causing a rapid rise in the local temperature of the device wherever avalanche may occur. Specifically GaAs has a thermal conductivity of 0.455 W/(cm-° K), compared to silicon's 1.412 W/(cm-° K), which is nearly three times as thermally conductive (See R. Muller and Kamins, T; “Device Electronics for Integrated Circuits,” (John Wiley, New York, 1977). p 32).

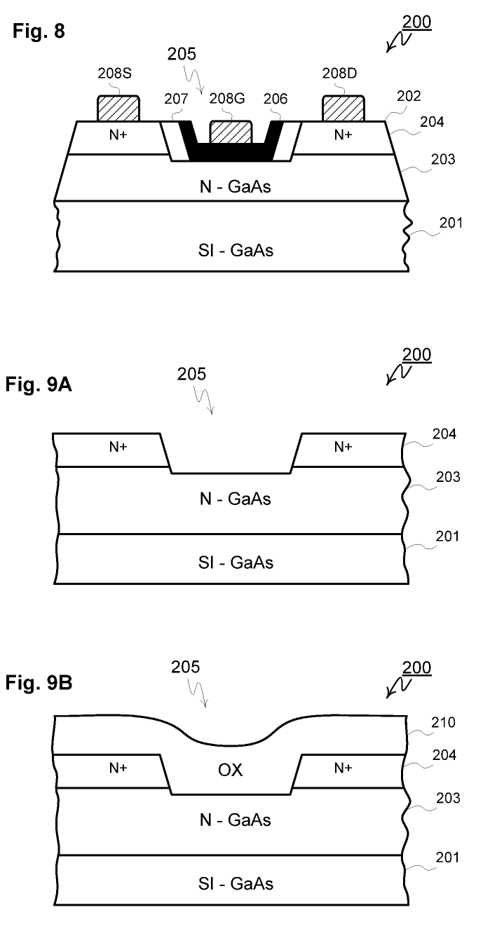

FIG. 8 illustrates one design that reduces MESFET gate leakage and impact ionization by eliminating the risk of the Schottky barrier touching or nearly touching the trench gate sidewall as a result of photomask misalignment. In MESFET cross section 200, trench gate 205 is formed in mesa 202 of N—GaAs epitaxial layer 203 formed atop semi-insulating substrate 201. N+ regions 204 contacted by metal contacts 208S and 208D comprise the transistor's source and drain regions, respectively, while gate Schottky metal 206 is contacted by metal contact 208G (typically constructed with the same metal deposition used to form 208S and 208D).

In this device, trench gate 205 has sidewall spacer oxides 207 lining its edges preventing Schottky metal 206 from touching the trench sidewalls. Compared to conventional MESFET structures, this sidewall spacer trench gated MESFET is unique in its low electric field, minimal leakage current along the trench sidewall, and insensitivity to photomask misalignment. It also prevents metal from ever coming in contact with the trench sidewall, eliminating the risk of unwanted metal residues on the trench sidewall.

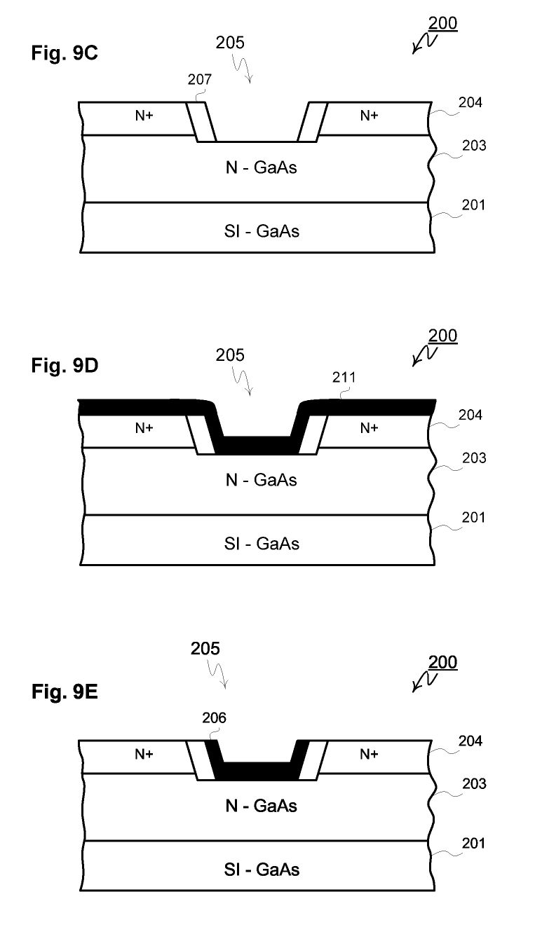

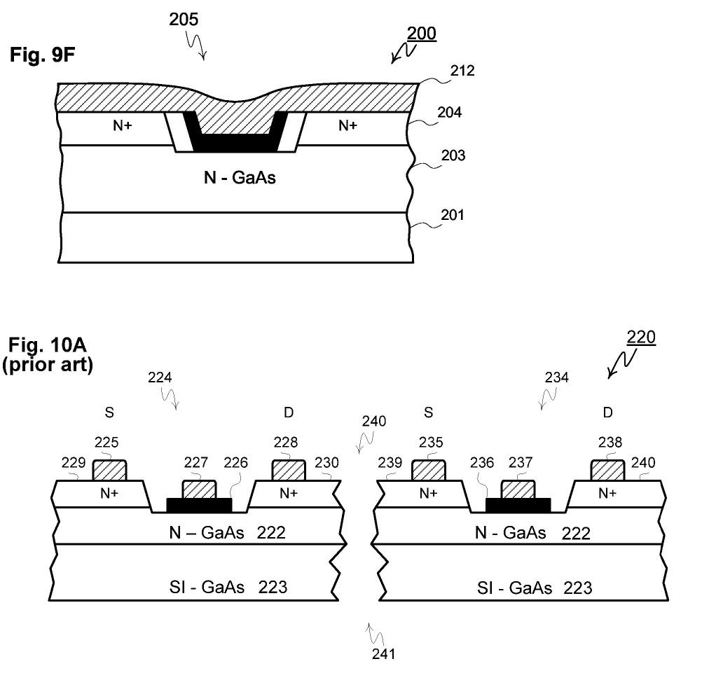

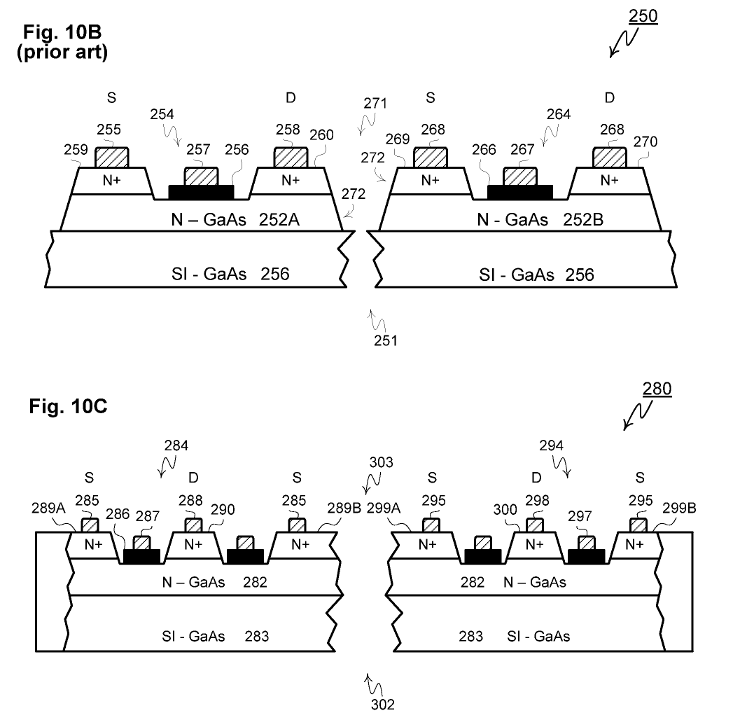

Fabrication of sidewall spacer trench-gate MESFET 200 is detailed in FIG. 9 starting with the photomasking and etching of trench gate 205 in epitaxial GaAs layer 203 formed on semi-insulating GaAs substrate 201 and having an N+ covering layer 204 atop said epitaxial layer 203. Trench 205 is etched to a depth deeper than said N+ layer 204. In power applications (other than prior art RF applications) trench 205 is etched to a final depth needed to form a normally off MESFET device with minimum I_{DSS} leakage.

Since GaAs cannot be thermally oxidized without forming a poor quality dielectric and causing changes in its crystalline stoichiometry, glass layer 210, typically comprising some form of silicon dioxide or silicon nitride, is next deposited using chemical vapor deposition, chemical reaction, or spin-on glass manufacturing method, as shown in FIG. 9B. Notice the semi-conformal glass 210 has its greatest vertical depth alongside the edges of trench 205. After etchback the only portion of glass layer 210 remaining is sidewall spacer oxide 207 filling the trench corners and covering its sidewall.

Next, as shown in FIG. 9D, Schottky metal 211 is deposited, typically through sputtering, evaporation, or organometalic chemical reaction methods followed by a masked etchback or by chemical mechanical polishing (CMP) to form gate metal 206 as shown in FIG. 9E. The Schottky metal 211 etchback must be sufficient to remove metal 206 from the surface of N+ layer 204 or a leaky gate characteristic will result. The removal from the surface may be achieved by slightly over-etching the Schottky metal down into the trench, or by employing chemical mechanical polishing (CMP) to remove it from the wafer's front surface. To achieve the flat surface shown in FIG. 9E, CMP is required.

Interconnect metal 212, typically gold, is then deposited as shown in FIG. 9F, followed by a masked metal etch to form the structure shown in FIG. 8. Although sidewall spacer MESFET device 200 is shown cross section as a single stripe device, it may be alternatively be implemented using the drain concentric design shown in FIG. 7.

Eliminating Breakdown with Low-Cost Processing

In order to reduce the manufacturing cost of a power MESFET by eliminating mesa etching, the device design must employ a concentric design to avoid edge breakdown. In cross section 220 in FIG. 10A, two adjacent MESFETs 224 and 234 are separated by a scribe street 240 to accommodate sawing. Saw kerf 241 illustrates the jagged edge resulting from sawing, transecting both source N+ 229 and drain N+ 230 of device 224. Similarly, MESFET 234 has its source 239 and drain 240 transected. Lengthwise, the gate must terminate at the die edge perpendicular to a saw cut giving rise to surface leakage between source region 239 and drain region 240. So while die 224 and 234 are separated by sawing, the die may be damaged through the manufacturing process.

FIG. 10B illustrates in cross section 250 a prior art solution for separating die 254 and die 264 using a mesa etch in scribe street 271 resulting in mesa edges 272. Sawing through substrate 253 to separate the die, results in saw cut 251. This mesa etch terminates the MESFET device without damaging active epitaxial layer 252A and 252B to the same degree as sawing does. Even so, an etched surface can exhibit surface states and excess leakage, especially affecting long term device reliability.

One solution to eliminate saw edge damage to active MESFET areas is to employ a concentric device design like shown in cross section 280 of FIG. 10C where device 284 contains drain 288 surrounded by ring shaped source 289A and 289B and where device 294 contains drain 298 surrounded by ring shaped source 299A and 299B. In this approach only source regions are sawed and therefore no drain-to-source or drain-to-gate leakage results from the sawing process.

MESFET Gate Variants

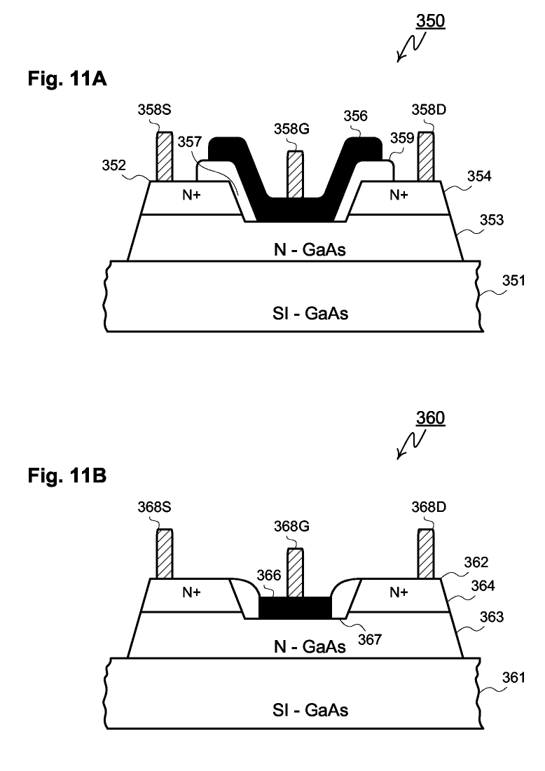

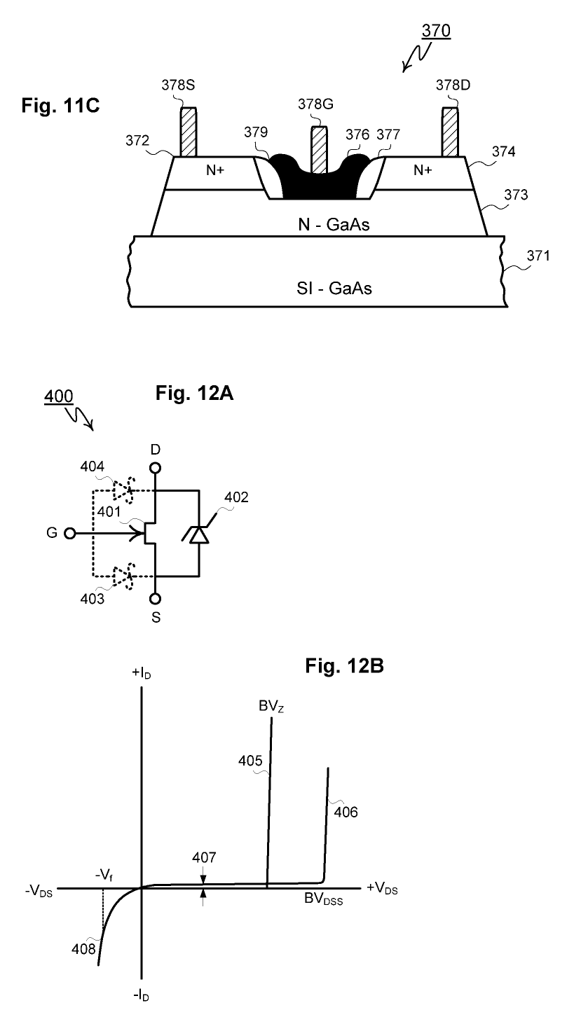

To minimize gate leakage and further protect and passivate the trench sidewalls, several variants of the sidewall-spacer MESFET 200 of FIG. 8 can be utilized. In FIG. 11A, MESFET 350 comprises a Schottky gate metal 356 separated on its sidewalls from epitaxial layer 353 and N+ layer 357 by sidewall spacer dielectric 357. Gate metal 356 does not touch N+ layer 354, but instead overlaps onto oxide 359 which separates it from the top surface of N+ layer 354. By eliminating sidewall and surface Schottky junction area between metal 356 and N+ layer 354, this design reduces both gate leakage and capacitance. The surface electric field is also reduced in the structure, with less impact ionization and a higher breakdown voltage. Fabrication of MESFET 350 follows the same procedure as that shown in FIG. 9, except that the sidewall spacer etchback shown in FIG. 9C is masked at the trench edges to produce surface oxide 359.

In another variant, MESFET 360 of FIG. 11B includes a Schottky gate metal region 366 smaller than the trench gate width resulting in space 367 between gate metal 366 and sidewall spacer oxide 369. Sidewall spacer oxide 369 is therefore not overlapped by Schottky metal 366. Fabrication of MESFET 360 follows the same procedure as that shown in FIG. 9, except that gate 366 is masked and etched to have a feature size smaller then the gate trench dimension.

In a third variant, MESFET 370 of FIG. 11C has a Schottky metal 376 masked and etched to a dimension comparable to the inside edge of sidewall space oxide 377 so that edge 3790 of gate Schottky metal 376 never overlaps onto N+ region 374. Fabrication follows the same procedure as that shown in FIG. 9, except that the feature size of gate 376 is drawn smaller in device 370 than that of device 200.

The use of the sidewall spacer in MESFETs 200, 350 and 370 also reduces on-resistance by minimizing the drift length L_{D} separating the Schottky gate and the N+ drain and source regions, and eliminating the sensitivity of on-resistance to gate-to-trench misalignment.

Asymmetric MESFET Voltage Clamping

While the origin of leakage and the magnitude of impact ionization in a MESFET can be reduced in a MESFET using the aforementioned techniques, the amount of energy than can be absorbed in avalanche remains limited. The avalanche power density of a GaAs MESFET is lower than that of a silicon-based power MOSFET for two reasons—first that the thermal resistance of most III-V materials is higher than silicon, and secondly, that unipolar devices have no P-N junction to exhibit a sharp low-impedance avalanche characteristic.

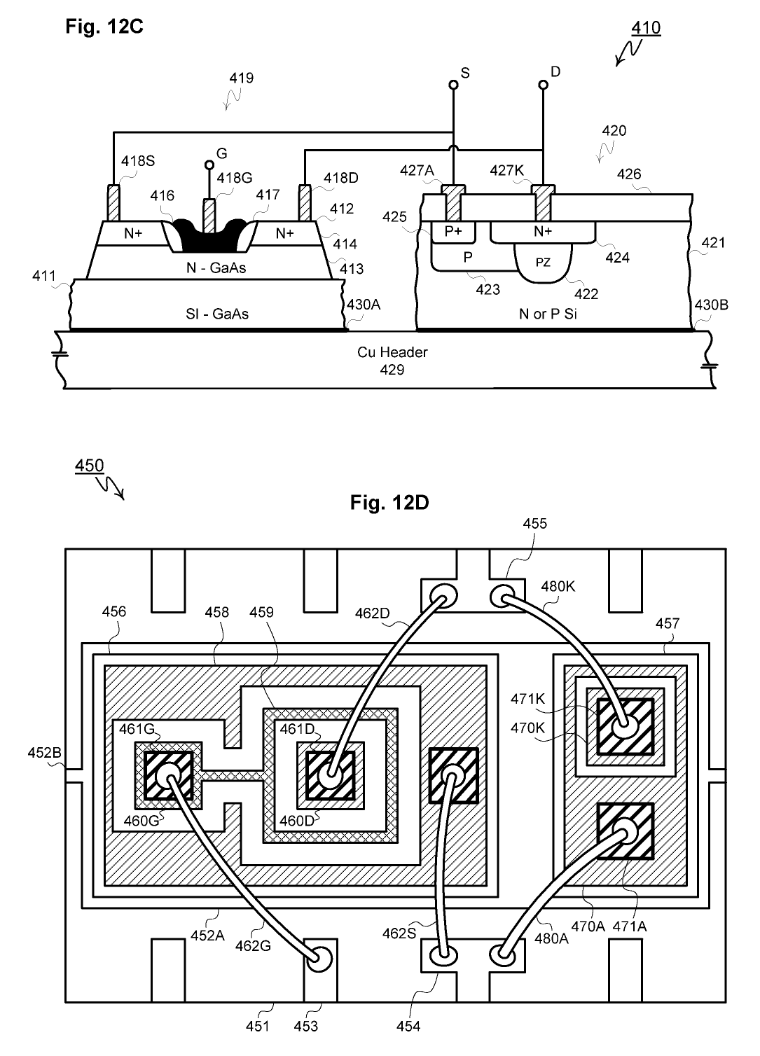

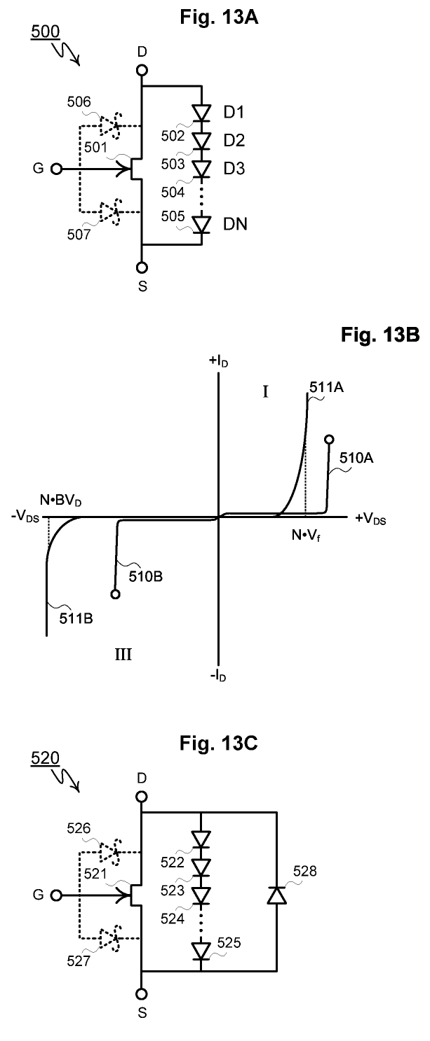

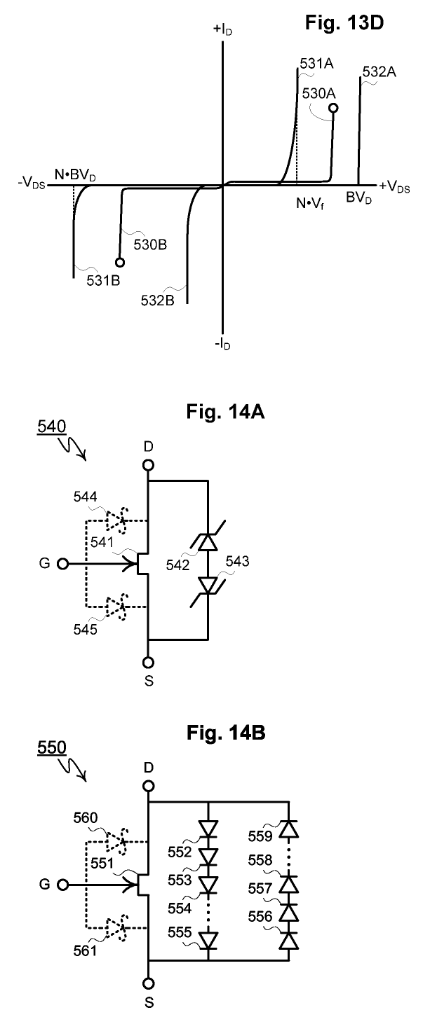

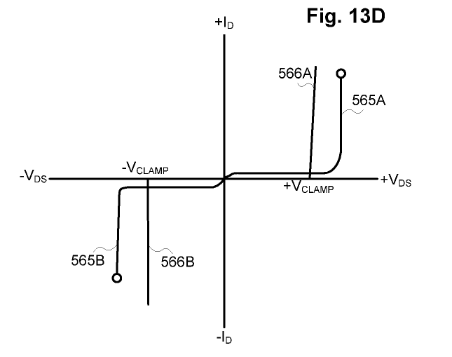

To prevent MESFET damage in avalanche, FIG. 12A illustrates the use of a voltage clamp 402 to limit the maximum drain-to-source voltage on MESFET 401. The clamped MESFET 400 shown is implemented using a low-breakdown avalanche diode, symbolically illustrated by a Zener diode 402. By limiting the maximum drain-to-source voltage, the Zener also protects the MESFET's Schottky gate diodes, specifically gate-to-drain diode 404 and gate-to-source diode 403. The blocking is asymmetric, however, since a reverse polarity connection will forward bias Zener diode 402, limiting the maximum voltage to well under one volt.

FIG. 12B illustrates the Zener breakdown 405 should be chosen to have a voltage BV_{Z} lower than the onset of avalanche 406 (having voltage BV_{DSS}) by at least one to two volts to guarantee that the majority of avalanche current flows through the Zener and not through the MESFET. In some cases, it may be desirable to choose the Zener voltage to be five or more volts above the MESFET's avalanche voltage as a guardband. The current-voltage characteristic of the combined device 400 is the parallel combination of the Zener and the MESFET. Accordingly device 400 will exhibit a leakage current 407 of magnitude I_{DSS} up till the onset of breakdown 405 in the Zener voltage clamp. In the reverse polarity, the forward biasing of the Zener diode limits the voltage to V_{F}, as illustrated by curve 408.

It should be noted here that any P-N junction breakdown mechanism resulting in a rapid rise in current for a small incremental voltage, i.e. having a low impedance breakdown, can achieve this clamping characteristic even if the breakdown mechanism is avalanche (or reach-through) and not a true Zener (tunneling) conduction mechanism.

While it is conceptually possible to integrate the Zener clamping diode into the MESFET itself, the manufacture of P-type GaAs is problematic, using uncommon materials and expensive fabrication procedures. Instead a multi-die approach can be employed combining a Zener diode in silicon, and a MESFET is GaAs or any other binary or compound semiconductor material. In this manner each device can be optimized for it most ideal properties without compromise.

For example in cross section 410 of FIG. 12C, MESFET 419 and silicon diode 420 are assembled onto a common lead frame 429 and attached by epoxy layers 430A and 430B. MESFET 419 comprises semi-insulating substrate 411, N—GaAs epitaxial layer 413, N+ layer 414, Schottky gate 416 with gate electrode 418G and optional sidewall spacer dielectric 417, drain electrode 418D, and source electrode 418S. Zener diode 420 comprises cathode 424 and cathode-electrode 427K, anode 422 and P-region 423, P+ contact region 425, and anode electrode 425. The diode shown is a buried Zener, where breakdown occurs below the surface at the underside of N+ region 424 where PZ region 422 touches it. Alternatively, a surface Zener could achieve the same protection function.

In FIG. 12C, fast voltage clamping is achieved by paralleling Zener 420 and MESFET 419 through wire bonds, thereby minimizing interdevice inductance, ringing, and voltage overshoot. To parallel the devices, the MESFET's drain electrode 418D is connected to Zener cathode 427K and the MESFET's source electrode 418S and Zener anode 427A. Die attach can be performed using conductive or non-conductive epoxy layer 430A and 430B since the substrate of the GaAs MESFET 419 is non-conductive. While MESFET 419 is shown as a mesa etched device, a drain concentric layout may also be used such as those in FIG. 7.

In FIG. 12D, a top view illustrates an example of bonding of Zener diode die 457 and MESFET die 456 mounted on die pad 452A. In the example shown, MESFET drain metal 460D (with passivation opening 461D) is wire bonded to package post 455 by bond wire 462D, which is also wire bonded to Zener cathode metal 470K (having passivation opening 471K) through wire bond 480K. Similarly, MESFET source metal 468 (with passivation opening 461S) is wire bonded to package post 454 by bond wire 462S, which is also wire bonded to Zener anode metal 470A (having passivation opening 471A) through wire bond 480A. Some details of the semiconductor device layout have been omitted from the bonding diagram of FIG. 12D for the sake of clarity.

Referring again to FIG. 12A, the schematic illustrates any polarity reversal across circuit 400 will cause Zener diode 402 to conduct in the forward biased direction, as illustrated by curve 408 in quadrant III (i.e. −I_{D}, −V_{DS}) of FIG. 12B. Such a clamped device is well suited for any application where reverse conduction is needed, i.e. where the polarity of the MESFET's current and applied voltage may reverse. This condition is especially common for synchronous rectifiers or applications driving inductors in push-pull circuit topologies. In such applications any attempted interruption in inductor current, even momentarily, can cause the inductor to change voltage rapidly in order to maintain current continuity, even developing voltages above or below the circuit's supply rails. If no diode conduction mechanism such as the forward biasing of Zener clamp 402 exists in the device and assuming the gate is biased to maintain the device in its off state, the MESFET's source-to-drain voltage would increase until MESFET 401 avalanches in the reverse polarity, potentially damaging the device.

So the invention of the of the Zener clamped MESFET diode not only protects the MESFET from avalanche-induced damage in the forward operating mode but it also enables the device to carry drain current in its reverse direction, regardless of its gate bias condition. The forward biasing of Zener diode 402 exhibits a voltage −V_{F}. If a lower voltage is desired, a Schottky diode can be paralleled with Zener diode 402 and optionally integrated into either the MESFET or the Zener. Depending on the gate biasing however, the MESFET's gate Schottky 526 or 527 may also forward bias carrying some of the current during reverse polarity conditions. The resulting drain electrical characteristic is asymmetric, having a lower voltage in the reverse polarity in quadrant III (−V, −I), than in quadrant I operation (+V, +I).

Another method to achieve MESFET voltage clamping is to employ a series of forward biased P-N diodes in parallel to the MESFET's drain-to-source terminals such as shown in circuit 500 of FIG. 13A. This approach is particularly important when no Zener diode is available. In this circuit, any number of similar or identical P-N diodes D1 to DN, are stacked series, e.g. as diodes 502, 503, 504, and 505, with the whole series stack wired in parallel to the drain-to-source terminals of MESFET 501. Voltage clamping is achieved by forward biasing the diode stack to limit the maximum voltage. So long as the number of diodes times the forward voltage V_{F} of any one diode is less than the avalanche voltage of the MESFET's drain to gate diode 506 (and therefore less than the drain-to-source avalanche of the MESFET), then the MESFET is voltage clamp protected in that polarity. As shown in FIG. 13B, the total forward drop illustrated by curve 511A is less than avalanche 510A, so that the MESFET is protected in this forward polarity, i.e. in quadrant I.

In the reverse polarity, i.e. in quadrant III, clamping structure 500 doesn't protect the device. In this case, the series diode clamp has a total voltage of N times the BV_{D} of each diode, the sum of which has a voltage (indicated by curve 511B) well beyond the MESFET's safe drain-to-source voltage 510B, and too high to protect drain to gate diode 507 intrinsic to MESFET 501. Such a circuit is not useful as a synchronous rectifier.

An alternative shown in FIG. 13C providing bidirectional protection for MESFET 520 requires the addition of diode 528 in parallel to (but oriented in the opposite polarity to) the series clamp comprising of forward biased diodes 522, 523, 524 and 525. As shown in the characteristics of FIG. 13D, this “anti-parallel” diode has no effect on the forward blocking characteristics of the series diode stack having voltage 531A, provided diode 532A has a higher blocking voltage BV_{D} than the series clamp voltage). In the reverse direction, diode 528 forward biases, and thereby limits the maximum reverse voltage to one V_{D} as illustrated by 532B. This voltage, while too low to use in normal reverse blocking operation, allows MESFET 521 to operate with reverse diode conduction. Circuit 520 is therefore useful as a synchronous rectifier, especially if diode 528 has a low forward voltage and minimal stored charge (e.g. if diode 528 is a Schottky diode).

Symmetric MESFET Voltage Clamping

To achieve symmetric voltage clamping for true bidirectional applications, the clamping diode protecting a MESFET must block bidirectionally, and ideally symmetrically. In circuit 540, FIG. 14A illustrates back-to-back Zener diodes 542 and 543 in parallel to MESFET 541. The clamping voltage in either direction is then V_{clamp}=±(V_{F}+BV_{Z}). The clamp also protects the MESFET's gate Schottky diodes 544 and 545.

Another bidirectional clamp is shown in circuit 550 of FIG. 14B where a stack of N series connected P-N diodes 552, 553, 554, and 555 is connected parallel to MESFET 551 and a second stack of series connected P-N diodes 556, 557, 558, 59 is connected in antiparallel orientation, i.e. in opposite direction to the first stack of diodes.

The number of series connected forward biased diodes is selected to have a total voltage less than that of the avalanche voltage of MESFET 551, namely N·V_{F}<BV_{DSS}. This principle illustrated in FIG. 14C where clamp voltage 566A has a voltage less than the MESFET's avalanche voltage shown by curve 565A. In the reverse polarity, clamp voltage 566B has a voltage less than the MESFET's avalanche voltage shown by curve 565B. Since the breakdown voltage of the sum of the series connected diodes is much greater than that of the antiparallel forward biased diodes, i.e. N·V_{F}<N·BV_{D}, then the forward biased characteristic determines the device's electrical properties while providing bidirectional protection.

What is claimed is:

1. A MESFET that comprises:
a drain;
a Schottky gate that laterally surrounds the drain; and
a source surrounding at least a portion of the Schottky gate.

2. The MESFET of claim 1 where the source entirely surrounds the Schottky gate.

3. The MESFET of claim 1 where the MESFET is made of GaAs.

4. The MESFET of claim 1 where the MESFET is normally off.

5. The MESFET of claim 1 where the drain has a rectangular shape.

6. The MESFET of claim 1 where the drain has a square shape.

7. The MESFET of claim 1 where the drain has an interdigitated shape.

8. The MESFET of claim 1 that includes a surface layer formed with a trench that has a base and two sidewalls and in which the Schottky gate is formed as a Schottky metal layer that overlays the trench and extends beyond the trench, with an oxide spacer preventing the Schottky metal layer from contacting the MESFET at locations not within the base of the trench.

9. The MESFET of claim 1 that includes a surface layer formed with a trench that has a base and two sidewalls and in which the Schottky gate is formed as a Schottky metal layer that overlays the base of the trench and is narrower than the greatest distance between the trench sidewalls.

10. The MESFET of claim 2 where the entire die is separated from other die by sawing through the source material.

11. The MESFET of claim 2 where no mesa etch is used to isolate the device.

12. A MESFET that includes:
a surface layer formed with a trench that has a base and two sidewalls; and
a Schottky gate formed as a Schottky metal layer overlaying a portion of the base of the trench without contacting the sidewalls.

13. A MESFET that comprises:
a drain;
a Schottky gate;
a source; and
a sidewall oxide spacer that isolates the Schottky gate from the drain and source.

14. A method for manufacturing a MESFET, the method comprising:
forming an N+ covering layer on an underlying epitaxial layer;
forming a trench within the N+ that extends through the N+ covering layer and into the underlying epitaxial layer;
depositing a glass layer over the N+ covering layer and trench;
forming a sidewall spacer within the trench by removing the portions of the glass layer that contact the N+ covering layer and the base of the trench;
depositing a Schottky metal layer over at least the trench;
forming a Schottky metal gate by removing any portions of the gate metal layer that contact the N+ covering layer;
depositing an interconnect metal layer over at least the Schottky metal gate; and
forming a metal interconnect by removing any portions of the gate metal layer that extend beyond the Schottky metal gate.

15. A method as recited in claim 14 in which the trench is formed to a final depth adequate to form a normally off MESFET device with minimum I_{DSS} leakage.

16. A method as recited in claim 14 in which the trench is formed by photomasking and etching.

17. A method as recited in claim 14 in which the glass layer is made of silicon dioxide or silicon nitride.

18. A method as recited in claim 14 in which the glass layer is deposited using chemical vapor deposition, chemical reaction, or spin-on glass manufacturing methods.

19. A method as recited in claim 14 that further comprises etching the glass layer to remove the portions of the glass layer that contact the N+ covering layer and the base of the trench.

20. A method as recited in claim 14 in which the Schottky metal layer is deposited using sputtering, evaporation, or organometalic chemical reaction methods.

21. A method as recited in claim 14 that further comprises etching the Schottky metal layer to remove any portions of the gate metal layer that extend beyond the Schottky metal gate.

22. A switching device that comprises:
a MESFET; and
a Zener diode connected in parallel with the MESFET where the breakdown of Zener diode is less than the breakdown voltage of the MESFET in its off state.

23. A switching device as recited in claim 22 in which the MESFET and Zener diode are formed on separate die included in a single package.

24. A switching device as recited in claim 22 in which the MESFET is formed using GaAs as it semiconducting material and the Zener diode is formed using silicon as its semiconducting material.

25. A switching device that comprises:
a MESFET; and
a voltage clamp connected in parallel with the MESFET where the voltage clamp includes a series connection of P-N diodes where the forward bias voltage of the voltage clamp is less than the breakdown voltage of the MESFET in its off state.

26. A switching device as recited in claim 25 where a second P-N junction diode is connected parallel to the MESFET but antiparallel to the voltage clamp.

27. A switching device that comprises:
a MESFET;
a voltage clamp connected in parallel with the MESFET where the voltage clamp includes first and second Zener diodes with the anode of the second diode connected to the anode of the first diode, the cathode of the first Zener diode connected to the source of the MESFET, and the cathode of the second Zener diode connected to the drain of the MESFET, and where the clamp voltage is less than the breakdown voltage of the MESFET in its off state.

28. A switching device that comprises:
a MESFET; and
a voltage clamp connected in parallel with the MESFET where the voltage clamp includes: a first series connection of P-N diodes connected in parallel with the MESFET; and a second series connection of P-N diodes connected anti-parallel to the MESFET; where the forward biased voltage of the clamp is less than the breakdown voltage of the MESFET in its off state.
